(19) United States
(12) Patent Application Publication
(10) Pub. No.: US 2024/0224582 A1
(43) Pub. Date: Jul. 4, 2024

(54) LIGHT EMITTING DEVICE AND FABRICATING METHOD THEREOF, AND LIGHT EMITTING APPARATUS

(71) Applicants: Beijing BOE Technology Development Co., Ltd., Beijijng (CN); BOE Technology Group Co., Ltd., Beijing (CN)

(72) Inventors: Tieshi Wang, Beijing (CN); Zhuo Chen, Beijing (CN)

(73) Assignees: Beijing BOE Technology Development Co., Ltd., Beijing (CN); BOE Technology Group Co., Ltd., Beijing (CN)

(21) Appl. No.: 17/925,376

(22) PCT Filed: Dec. 27, 2021
(86) PCT No.: PCT/CN2021/141752

§ 371 Date: Nov. 15, 2022

(51) Int. Cl. H10K 50/84; H10K 50/115; H10K 50/85

(52) U.S. Cl. CPC H10K 50/846; H10K 50/115; H10K 50/85

(57) ABSTRACT

A light emitting device and a fabricating method thereof, and a light emitting apparatus, which relates to the technical field of semiconductors. The light emitting device includes: a substrate, and a luminescent layer and an additional component that are provided on one side of the substrate, the additional component is capable of having a chemical reaction with water and oxygen, and a reaction rate constant of the additional component with water and oxygen is greater than a reaction rate constant of the luminescent layer with water and oxygen; and the additional component is provided in a same layer as the luminescent layer and/or in a different layer from the luminescent layer.

### TECHNICAL FIELD

The present disclosure relates to the technical field of semiconductors and more particularly, to a light emitting device and a fabricating method thereof, and a light emitting apparatus.

### BACKGROUND

Organic Light Emitting Diodes (OLED) have the advantages such as self-illumination, a wide visual angle, a high reaction speed, a high luminous efficiency, a low operating voltage and a simple manufacture procedure, and thus it is known as the next generation of hotspot light emitting device.

Quantum-dot Light Emitting Diodes (QLED) have a narrower emission spectrum, purer displaying colors, and a wider color gamut. Therefore, QLEDs have been paid much attention in the industry, and have become a competitive candidate for the next generation of displaying techniques.

### SUMMARY

The present disclosure provides a light emitting device, wherein the light emitting device includes: a substrate, and a luminescent layer and an additional component that are provided on one side of the substrate, the additional component is capable of having a chemical reaction with water and oxygen, and a reaction rate constant of the additional component with water and oxygen is greater than a reaction rate constant of the luminescent layer with water and oxygen; and

the additional component is provided in a same layer as the luminescent layer and/or in a different layer from the luminescent layer.

In an alternative implementation, the additional component and the luminescent layer are arranged in a same layer, the additional component and the luminescent layer are mixed, and a molar volume fraction of the luminescent layer is greater than a molar volume fraction of the additional component.

In an alternative implementation, the additional component and the luminescent layer are arranged in different layers, the additional component is provided between the luminescent layer and the substrate, or the additional component is provided on one side of the luminescent layer that is away from the substrate.

In an alternative implementation, a material of the additional component includes at least one of a metal, a metal oxide and an organometallic compound.

In an alternative implementation, a material of the additional component includes at least one of an organic compound of lithium, an organic compound of sodium, an organic compound of zinc, an organic compound of cadmium, an organic compound of iron and an organic compound of titanium.

In an alternative implementation, a material of the additional component includes at least one of diethyl zinc, dimethyl zinc, dibutyl zinc, diphenyl zinc, diethyl cadmium, dimethyl cadmium, dibutyl cadmium, diphenyl cadmium, butyl lithium, tert-butyl lithium, methyl lithium and benzyl lithium.

In an alternative implementation, a thickness of the additional component is greater than or equal to 0.1 nm, and less than or equal to 10 nm.

In an alternative implementation, the luminescent layer includes an organic luminescent material or a quantum dot.

In an alternative implementation, the light emitting device further includes at least one of a first electrode, a hole injection layer, a hole transporting layer, an electron transporting layer, an electron injection layer, a second electrode, an optical-extraction layer and an encapsulation layer;

the first electrode, the hole injection layer, the hole transporting layer, the luminescent layer, the electron transporting layer, the electron injection layer, the second electrode, the optical-extraction layer and the encapsulation layer are arranged in stack on one side of the substrate, and the first electrode is close to the substrate; or the first electrode, the electron injection layer, the electron transporting layer, the luminescent layer, the hole transporting layer, the hole injection layer, the second electrode, the optical-extraction layer and the encapsulation layer are arranged in stack on one side of the substrate, and the first electrode is close to the substrate; and

the position of the additional component includes at least one of: provided between at least one group of neighboring film layers among the substrate, the first electrode, the hole injection layer, the hole transporting layer, the luminescent layer, the electron transporting layer, the electron injection layer, the second electrode, the optical-extraction layer and the encapsulation layer, provided on one side of the encapsulation layer that is away from the substrate, and doped in at least one of the first electrode, the hole injection layer, the hole transporting layer, the luminescent layer, the electron transporting layer, the electron injection layer, the second electrode, the optical-extraction layer and the encapsulation layer.

In an alternative implementation, the light emitting device includes a first functional layer, and the first functional layer is the first electrode, the hole injection layer, the hole transporting layer, the luminescent layer, the electron transporting layer, the electron injection layer or the second electrode; and

the first functional layer is doped by the additional component, and a doping proportion of the additional component in the first functional layer is greater than or equal to 0.1%, and less than or equal to 10%.

In an alternative implementation, the light emitting device includes a second functional layer, and the second functional layer includes the optical-extraction layer or the encapsulation layer; and

the second functional layer is doped by the additional component, and a doping proportion of the additional component in the second functional layer is greater than or equal to 0.1%, and less than or equal to 100%.

In an alternative implementation, the light emitting device includes the electron transporting layer, a material of the electron transporting layer includes a compound of a first metal, and a material of the additional component doped in the luminescent layer includes at least one of the first metal, an oxide of the first metal and an organic compound of the first metal.

The present disclosure provides a light emitting apparatus, wherein the light emitting apparatus includes the light emitting device according to any one of the above embodiments.

The present disclosure provides a fabricating method of a light emitting device, wherein the fabricating method includes:
providing a substrate; and
forming a luminescent layer and an additional component on one side of the substrate, wherein the additional component is capable of having a chemical reaction with water and oxygen, and a reaction rate constant of the additional component with water and oxygen is greater than a reaction rate constant of the luminescent layer with water and oxygen:
wherein the additional component is provided in a same layer as the luminescent layer and/or in a different layer from the luminescent layer.

In an alternative implementation, the step of forming the luminescent layer and the additional component on one side of the substrate includes at least one of:
providing a first solution containing a material of the additional component, and coating the first solution by spin coating, spray coating or blade coating, to form the additional component;
forming the additional component by vapor deposition; and
forming the additional component by sputtering.

In an alternative implementation, the light emitting device further includes at least one of a first electrode, a hole injection layer, a hole transporting layer, an electron transporting layer, an electron injection layer, a second electrode, an optical-extraction layer and an encapsulation layer;
the light emitting device includes a third functional layer, the third functional layer is the first electrode, the hole injection layer, the hole transporting layer, the luminescent layer, the electron transporting layer, the electron injection layer, the second electrode, the optical-extraction layer or the encapsulation layer, and the third functional layer is doped by the additional component; and
the step of forming the luminescent layer and the additional component on one side of the substrate includes at least one of:
providing a second solution containing a material of the third functional layer and a material of the additional component, and coating the second solution by spin coating, spray coating or blade coating, to form the additional component doped in the third functional layer;
by vapor deposition, vapor-depositing the material of the third functional layer and the material of the additional component at the same time, to form the additional component doped in the third functional layer; and
by sputtering, sputtering the material of the third functional layer and the material of the additional component at the same time, to form the additional component doped in the third functional layer.

The above description is merely a summary of the technical solutions of the present disclosure. In order to more clearly know the elements of the present disclosure to enable the implementation according to the contents of the description, and in order to make the above and other purposes, features and advantages of the present disclosure more apparent and understandable, the particular embodiments of the present disclosure are provided below.

### BRIEF DESCRIPTION OF THE DRAWINGS

In order to more clearly illustrate the technical solutions of the embodiments of the present disclosure or the related art, the figures that are required to describe the embodiments or the related art will be briefly described below. Apparently, the figures that are described below are embodiments of the present disclosure, and a person skilled in the art can obtain other figures according to these figures without paying creative work. It should be noted that the proportions in the drawings are merely illustrative and do not indicate the actual proportions.

FIG. 1 schematically shows a schematic sectional structural diagram of a first type of light emitting device;

FIG. 2 schematically shows a schematic sectional structural diagram of a second type of light emitting device;

FIG. 3 schematically shows a schematic sectional structural diagram of a third type of light emitting device;

FIG. 4 schematically shows a comparison between the life curves of a light emitting device provided with an additional component and a light emitting device not provided with an additional component;

FIG. 5 schematically shows a schematic sectional structural diagram of a fourth type of light emitting device;

FIG. 6 schematically shows a schematic sectional structural diagram of a fifth type of light emitting device;

FIG. 7 schematically shows a schematic sectional structural diagram of a sixth type of light emitting device;

FIG. 8 schematically shows a schematic sectional structural diagram of a seventh type of light emitting device; and

FIG. 9 schematically shows a schematic sectional structural diagram of an eighth type of light emitting device.

### DETAILED DESCRIPTION

In order to make the objects, the technical solutions and the advantages of the embodiments of the present disclosure clearer, the technical solutions of the embodiments of the present disclosure will be clearly and completely described below with reference to the drawings of the embodiments of the present disclosure. Apparently, the described embodiments are merely certain embodiments of the present disclosure, rather than all of the embodiments. All of the other embodiments that a person skilled in the art obtains on the basis of the embodiments of the present disclosure without paying creative work fall within the protection scope of the present disclosure.

In the drawings, in order for clarity, the thicknesses of the layers, the films, the panels, the regions and so on are exaggerated. The exemplary embodiments are described with reference to the cross-sectional views of the schematic diagrams as idealized embodiments herein. Accordingly, deviations from the shapes of the figures as the result of, for example, fabricating techniques and/or tolerances can be predicted. Therefore, the embodiments described herein should not be interpreted as limited to the particular shapes of the regions shown herein, but should include the deviations in terms of the shapes caused by, for example, fabrication. For example, a region illustrated or described as flat may typically have a rough and/or nonlinear feature. Moreover, an illustrated sharp angle may be rounded. Therefore, the regions shown in the drawings are essentially illustrative, and their shapes are not intended to illustrate the accurate shapes of the regions, and are not intended to limit the scopes of the claims.

As used herein, the term “and/or” includes any one of and all of the combinations of one or more of the related listed items. As can be further understood, the term “include” or “comprise”, when used in this specification, indicates the existence of the stated feature, region, entirety, step, operation, element and/or component, but does not exclude the existence or addition of one or more other features, regions, entireties, steps, operations, elements, components and/or combinations thereof.

Because the organic luminescent material in OLEDs or the quantum-dot material in QLEDs very easily reacts with water and oxygen, the light-emission performance of the light emitting devices is deteriorated or even fails.

In order to solve that problem, the present disclosure provides a light emitting device. Referring to FIG. 1 to FIG. 3, FIG. 1 to FIG. 3 show schematic sectional structural diagrams of several light emitting devices. As shown in FIG. 1 to FIG. 3, the light emitting device includes: a substrate 11, and a luminescent layer 12 and an additional component 13 that are provided on one side of the substrate 11, the additional component 13 is capable of having a chemical reaction with water and oxygen, and the reaction rate constant of the additional component 13 with water and oxygen is greater than the reaction rate constant of the luminescent layer 12 with water and oxygen.

The additional component 13 is provided in the same layer as the luminescent layer 12 and/or in a different layer from the luminescent layer 12.

Optionally, as shown in FIG. 1, the additional component 13 and the luminescent layer 12 are arranged in the same layer. For example, the additional component 13 and the luminescent layer 12 may be mixed, and the molar volume fraction of the luminescent layer 12 is greater than the molar volume fraction of the additional component 13. As shown in FIG. 1, the material of the additional component 13 is uniformly doped in the luminescent layer 12.

It should be noted that that the molar volume fraction of the luminescent layer 12 is greater than the molar volume fraction of the additional component 13 refers to that the doping of the additional component 13 in the luminescent layer 12 is a small-amount doping, and the host is the material of the luminescent layer 12.

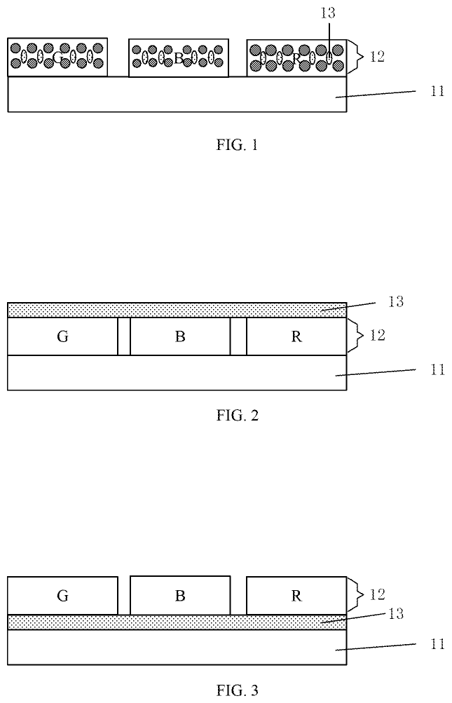

Optionally, the additional component 13 and the luminescent layer 12 are arranged in different layers. For example, as shown in FIG. 3, the additional component 13 is provided between the substrate 11 and the luminescent layer 12. Alternatively, as shown in FIG. 2, the additional component 13 is provided on the side of the luminescent layer 12 that is away from the substrate 11.

As shown in FIG. 2 or FIG. 3, the additional component 13 may be, as an independent film layer, provided between the substrate 11 and the luminescent layer 12 or provided on the side of the luminescent layer 12 that is away from the substrate 11.

The substrate 11 may, for example, be glass, a polyimide thin film, a silicon wafer and so on, which is not limited in the present disclosure.

In the present embodiment, if the reaction rate constant of the material of the luminescent layer with water and oxygen is k, and the reaction rate constant of the material of the additional component with water and oxygen is k2, then k2>k1. The materials of the additional component that satisfy k2>k1 are materials having a high water-oxygen reactivity.

In the present embodiment, that the reaction rate constant of the additional component 13 with water and oxygen is greater than the reaction rate constant of the luminescent layer 12 with water and oxygen refers to that the reaction rate constant of the additional component 13 with water is greater than the reaction rate constant of the luminescent layer 12 with water; or the reaction rate constant of the additional component 13 with oxygen is greater than the reaction rate constant of the luminescent layer 12 with oxygen; or the reaction rate constant of the additional component 13 with water is greater than the reaction rate constant of the luminescent layer 12 with water and the reaction rate constant of the additional component 13 with oxygen is greater than the reaction rate constant of the luminescent layer 12 with oxygen.

In a particular implementation, the material of the additional component 13 may include but is not limited to metals such as lithium, sodium, zinc, cadmium, iron and titanium, and organic or inorganic compounds thereof. For example, the material of the additional component 13 may include but is not limited to one or more of diethyl zinc, dimethyl zinc, dibutyl zinc, diphenyl zinc, diethyl cadmium, dimethyl cadmium, dibutyl cadmium, diphenyl cadmium, butyl lithium, tert-butyl lithium, methyl lithium and benzyl lithium.

The function of absorbing water and oxygen of the additional component 13 will be described below by taking the case as an example in which the material of the additional component 13 includes diethyl zinc. Diethyl zinc has a reaction when contacting water and oxygen at a normal temperature. The reaction equations of diethyl zinc with excessive water and oxygen are:

$$Zn {( {C}_{2} {H}_{5} )}_{2} + 7 {O}_{2} ZnO + 4 {CO}_{2} + 5 {H}_{2} O ; and$$

$${Zn ( {C}_{2} {H}_{5} )}_{2} + {H}_{2} O ZnO + 2 {C}_{2} {H}_{6} .$$

Optionally, the material of the additional component 13 may include diphenyl zinc, which has a reaction when contacting water and oxygen at a normal temperature, to generate zinc oxide and other products. It should be noted that the reaction process of diethyl zinc and water and oxygen is very complicated, and different amounts of water and oxygen result in generating different reaction products. The above reaction equations are merely description on one of the cases as an example, and the particular reaction process and result are not limited in the present disclosure.

In the present embodiment, the additional component 13 may be provided at one or more of the following positions: on the side of the luminescent layer 12 that is close to the substrate 11, on the side of the luminescent layer 12 that is away from the substrate 11, and doped in the luminescent layer 12.

If the additional component 13 is provided on the side of the luminescent layer 12 that is close to the substrate 11, then the additional component 13 may be provided as an independent film layer (as shown in FIG. 3), and may also be doped in a functional layer between the luminescent layer 12 and the substrate 11. Because the material of the additional component has a higher reaction rate constant with water and oxygen, it may absorb the water and oxygen inside the light emitting device, to prevent the material of the luminescent layer from reacting with the water and oxygen, which may improve the capacity of resisting water and oxygen of the light emitting device, thereby facilitating to prolong the life of the device.

If the additional component 13 is doped in the luminescent layer 12, as shown in FIG. 1, then the material of the additional component and the material of the luminescent layer are physically mixed, and do not have a chemical reaction therebetween. Because the material of the additional component has a higher reaction rate constant with water and oxygen, it may preferentially absorb the water and oxygen inside the luminescent layer 12 before the material of the luminescent layer and water and oxygen react, to effectively prevent the material of the luminescent layer from reacting with the water and oxygen, which may improve the capacity of resisting water and oxygen of the light emitting device, thereby facilitating to prolong the life of the device.

If the additional component 13 is provided on the side of the luminescent layer 12 that is away from the substrate 11, then the additional component 13 may be provided as an independent film layer (as shown in FIG. 2), and may also be doped in a functional layer on the side of the luminescent layer 12 that is away from the substrate 11. Because the material of the additional component has a higher reaction rate constant with water and oxygen, it may absorb the water and oxygen diffusing from the exterior of the device to the interior of the device, to prevent the material of the luminescent layer from reacting with the water and oxygen, which may improve the capacity of resisting water and oxygen of the light emitting device, thereby facilitating to prolong the life of the device, facilitating to improve the environmental stability of the light emitting device, and prolong the storing duration of the device.

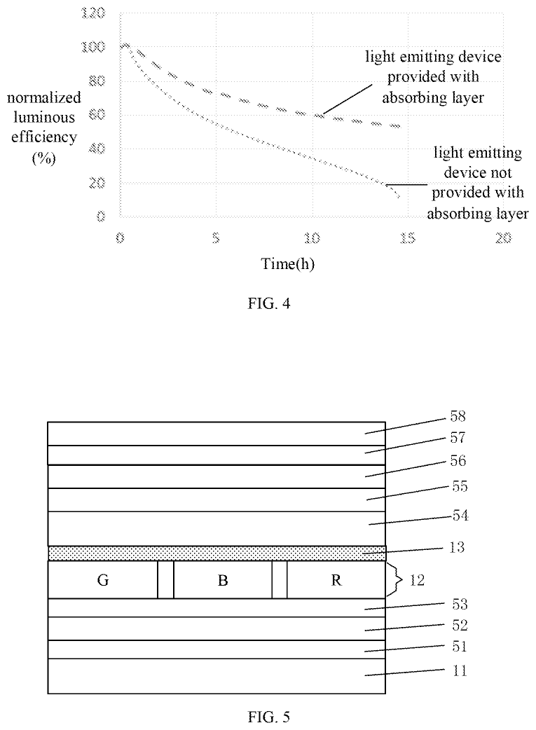

Referring to FIG. 4. FIG. 4 shows the life curves of a light emitting device provided with the additional component and a light emitting device not provided with the additional component. As shown in FIG. 4, in the process of the aging of the device, the decreasing of the luminous efficiency of the light emitting device provided with the additional component 13 is slower, which indicates that the service life of the light emitting device provided with the additional component 13 is greatly increased.

In the light emitting device according to the present embodiment, the additional component 13 having a higher water-oxygen reactivity is introduced into the light emitting device, and the additional component 13 may absorb the water and oxygen inside the device and diffusing from the exterior of the device to the interior of the device, and thus may prevent the material of the luminescent layer from reacting with the water and oxygen, which may improve the capacity of resisting water and oxygen of the light emitting device, thereby facilitating to prolong the life of the device.

In the present embodiment, the material of the luminescent layer 12 may include an organic luminescent material or a quantum dot and so on. The organic luminescent material may particularly include an organic dye, a complex material and so on. The material of the quantum dot may particularly include but is not limited to CdS, CdSe, ZnSe, InP, PbS, CsPbCl₃, CsPbBr₃, CsPhI₃, CdS/ZnS, CdSe/ZnS, InP/ZnS, PbS/ZnS, CsPbCl₃/ZnS, CsPbBr₃/ZnS, and CsPhI₃/ZnS.

In order to realize color light emission, as shown in FIG. 1 to FIG. 3, the quantum-dot layer 13 may include a red-color luminescent layer R, a green-color luminescent layer G and a blue-color luminescent layer B. The red-color luminescent layer R, the green-color luminescent layer G and the blue-color luminescent layer B are insulated from each other. In the practical structure, in order to prevent short circuiting between the red-color luminescent layer R, the green-color luminescent layer G and the blue-color luminescent layer B, an insulating pixel defining layer (not shown in the figures) may be provided between the luminescent layers of two neighboring sub-pixels, and the structure of the pixel defining layer may be configured according to practical demands.

The light emitting device according to the present embodiment may be a photoluminescent device or an electroluminescent device, which is not limited in the present disclosure.

Optionally, the material of the additional component 13 may include at least one of a metal, a metal oxide and an organometallic compound.

Particularly, the material of the additional component 13 may include at least one of organometallic compounds such as an organic compound of lithium, an organic compound of sodium, an organic compound of zinc, an organic compound of cadmium, an organic compound of iron and an organic compound of titanium.

For example, the material of the additional component 13 may include at least one of organometallic compounds such as diethyl zinc, dimethyl zinc, dibutyl zinc, diphenyl zinc, diethyl cadmium, dimethyl cadmium, dibutyl cadmium, diphenyl cadmium, butyl lithium, tert-butyl lithium, methyl lithium and benzyl lithium.

In an alternative implementation, the additional component 13 may be provided as an independent film layer, and the thickness of the additional component 13 may be greater than or equal to 0.1 nm, and less than or equal to 10 nm. For example, the thickness of the additional component 13 may be 5 nm and so on.

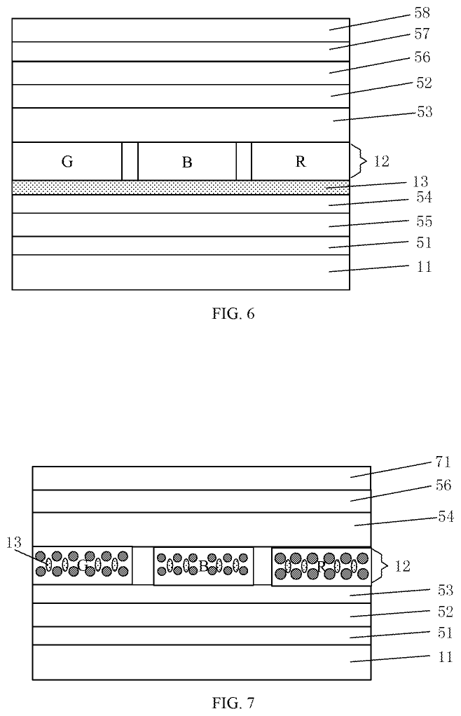

In a particular implementation, the light emitting device may be an electroluminescent device. In order to realize the electroluminescence and increase the luminous efficiency of the electroluminescent device, the light emitting device may further include at least one of a first electrode 51, a hole injection layer 52, a hole transporting layer 53, an electron transporting layer 54, an electron injection layer 55, a second electrode 56, an optical-extraction layer 57 and an encapsulation layer 58, as shown in FIG. 5 and FIG. 6.

The work functions of the first electrode 51 and the second electrode 56 may be equal or unequal, and the first electrode 51 and the second electrode 56 may be exchanged. The first electrode 51 may be a transmitting electrode or a half-transmitting reflecting electrode. If the first electrode 51 is a half-transmitting reflecting electrode or a reflecting electrode, the first electrode 51 may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (for example, a mixture of Ag and Mg). In one or more embodiments, the first electrode 51 may be of a multilayer structure, and includes a reflecting layer and/or a half-transmitting reflecting layer formed by using any of the materials described above, and a transparent electrically conductive layer formed by using indium tin oxide (ITO), indium zinc oxide (IZO), zinc oxide (ZnO), indium tin zinc oxide (ITZO) and so on. For example, the first electrode 51 may be multiple metal layers, and may have a laminated structure of ITO/Ag/ITO.

The hole transporting layer 53 is mainly used for the transmission of the holes, and its material may include but is not limited to an organic hole transmitting material such as CBP, NPB and TPD, and an inorganic hole transmitting material such as nickel oxide, tungsten oxide, molybdenum oxide, cuprous oxide and vanadium oxide.

The main function of the hole injection layer 52 is to reduce the hole injection barrier potential, and increase the hole injection efficiency. It may be fabricated by using materials such as PSS: PEDOT and NiOx, and may also be fabricated by P-type doping to a hole transmitting material.

The electron transporting layer 54 is mainly used for the transmission of the electrons, and its material may include but is not limited to zinc oxide, magnesium zinc oxide, aluminium zinc oxide, tin oxide and titanium oxide.

The electron injection layer 55 is mainly used to reduce the barrier potential of the electron injection from the cathode, to enable the electrons to be effectively injected into the luminescent layer 12 from the cathode, and its material may include but is not limited to lithium fluoride, magnesium boride, magnesium fluoride and aluminium oxide.

The optical-extraction layer 57 is used to increase the luminous efficiency of a top-emission light emitting device, to enable the light rays originally restricted inside the device to exit the device. The optical-extraction layer 57 may include an organic or inorganic transparent material of a high refractive index.

The encapsulation layer 58 is used to protect the internal structure of the light emitting device, and may include an organic packaging film layer and an inorganic packaging film layer. It should be noted that that the additional component 13 is doped in the encapsulation layer 58 refers to that the additional component is doped in the organic packaging film layer in the encapsulation layer 58.

In a particular implementation, the positions of the hole injection layer 52, the hole transporting layer 53, the electron transporting layer 54 and the electron injection layer 55, according to the types of the first electrode 51 and the second electrode 56, have multiple implementations.

In the first implementation, as shown in FIG. 5, the first electrode 51, the hole injection layer 52, the hole transporting layer 53, the luminescent layer 12, the electron transporting layer 54, the electron injection layer 55, the second electrode 56, the optical-extraction layer 57 and the encapsulation layer 58 are arranged in stack on one side of the substrate 11, and the first electrode 51 is closest to the substrate 11. In the present implementation, the work function of the first electrode 51 is greater than or equal to the work function of the second electrode 56. The first electrode 51 may be the anode, and the second electrode 56 may be the cathode.

The light emitting device according to the present implementation is of an uprightly placed structure. The hole injection layer 52, the hole transporting layer 53, the electron transporting layer 54, the electron injection layer 55, the optical-extraction layer 57 and the encapsulation layer 58 may be selectively provided according to practical demands.

The position of the additional component 13 includes at least one of: provided as an independent film layer between at least one group of neighboring film layers among the substrate 11, the first electrode 51, the hole injection layer 52, the hole transporting layer 53, the luminescent layer 12, the electron transporting layer 54, the electron injection layer 55, the second electrode 56, the optical-extraction layer 57 and the encapsulation layer 58, provided as an independent film layer on the side of the encapsulation layer 58 that is away from the substrate 11, and doped in at least one of the first electrode 51, the hole injection layer 52, the hole transporting layer 53, the luminescent layer 12, the electron transporting layer 54, the electron injection layer 55, the second electrode 56, the optical-extraction layer 57 and the encapsulation layer 58.

The one group of neighboring film layers refer to two neighboring film layers in the normal direction of the substrate 11 (i.e., the direction from the substrate 11 pointing to the luminescent layer 12) in the light emitting device.

Particularly, the additional component 13 may be provided at one or more of the following positions: between the substrate 11 and the first electrode 51, between the first electrode 51 and the hole injection layer 52, between the hole injection layer 52 and the hole transporting layer 53, between the hole transporting layer 53 and the luminescent layer 12, between the luminescent layer 12 and the electron transporting layer 54 (as shown in FIG. 5), between the electron transporting layer 54 and the electron injection layer 55, between the electron injection layer 55 and the second electrode 56, between the second electrode 56 and the optical-extraction layer 57, and between the optical-extraction layer 57 and the encapsulation layer 58; on the side of the encapsulation layer 58 that is away from the substrate 11; and doped in the first electrode 51, doped in the hole injection layer 52, doped in the hole transporting layer 53, doped in the luminescent layer 12, doped in the electron transporting layer 54, doped in the electron injection layer 55, doped in the second electrode 56, doped in the optical-extraction layer 57, and doped in the encapsulation layer 58.

In the second implementation, as shown in FIG. 6, the first electrode 51, the electron injection layer 55, the electron transporting layer 54, the luminescent layer 12, the hole transporting layer 53, the hole injection layer 52, the second electrode 56, the optical-extraction layer 57 and the encapsulation layer 58 are arranged in stack on one side of the substrate 11, and the first electrode 51 is close to the substrate 11. In the present implementation, the work function of the first electrode 51 is less than or equal to the work function of the second electrode 56. The first electrode 51 may be the cathode, and the second electrode 56 may be the anode.

The light emitting device according to the present implementation is of an inversely placed structure. The hole injection layer 52, the hole transporting layer 53, the electron transporting layer 54, the electron injection layer 55, the optical-extraction layer 57 and the encapsulation layer 58 may be selectively provided according to practical demands.

The position of the additional component 13 includes at least one of: provided as an independent film layer between at least one group of neighboring film layers among the substrate 11, the first electrode 51, the electron injection layer 55, the electron transporting layer 54, the luminescent layer 12, the hole transporting layer 53, the hole injection layer 52, the second electrode 56, the optical-extraction layer 57 and the encapsulation layer 58, provided as an independent film layer on the side of the encapsulation layer 58 that is opposite to the substrate 11, and doping in at least one of the first electrode 51, the electron injection layer 55, the electron transporting layer 54, the luminescent layer 12, the hole transporting layer 53, the hole injection layer 52, the second electrode 56, the optical-extraction layer 57 and the encapsulation layer 58.

The one group of neighboring film layers refer to two neighboring film layers in the normal direction of the substrate 11 (i.e., the direction from the substrate 11 pointing to the luminescent layer 12) in the light emitting device.

Particularly, the additional component 13 may be provided at one or more of the following positions: between the substrate 11 and the first electrode 51, between the first electrode 51 and the electron injection layer 55, between the electron injection layer 55 and the electron transporting layer 54, between the electron transporting layer 54 and the luminescent layer 12 (as shown in FIG. 6), between the luminescent layer 12 and the hole transporting layer 53, between the hole transporting layer 53 and the hole injection layer 52, between the hole injection layer 52 and the second electrode 56, between the second electrode 56 and the optical-extraction layer 57, and between the optical-extraction layer 57 and the encapsulation layer 58; on the side of the encapsulation layer 58 that is away from the substrate 11; and doped in the first electrode 51, doped in the electron injection layer 55, doped in the electron transporting layer 54, doped in the luminescent layer 12, doped in the hole transporting layer 53, doped in the hole injection layer 52, doped in the second electrode 56, doped in the optical-extraction layer 57, and doped in the encapsulation layer 58.

Optionally, the light emitting device includes a first functional layer, and the first functional layer may be the first electrode 51, the hole injection layer 52, the hole transporting layer 53, the luminescent layer 12, the electron transporting layer 54, the electron injection layer 55 or the second electrode 56.

The first functional layer is doped by the additional component 13, and the doping proportion of the additional component 13 in the first functional layer may be greater than or equal to 0.1%, and less than or equal to 10%.

By doping the material of the additional component having a higher water-oxygen reactivity in the first functional layer, the water and oxygen inside the light emitting device may be absorbed, which improves the capacity of resisting water and oxygen of the device, thereby facilitating to prolong the life of the device. Furthermore, the doping proportion of 0.1% to 10% of the additional component 13 in the first functional layer, in an aspect, may ensure that the additional component 13 has little influence on the electrical property of the first functional layer, and, in another aspect, may satisfy the demand of the interior of the device on the absorption of the water and oxygen.

Optionally, the light emitting device includes a second functional layer, and the second functional layer may be the optical-extraction layer 57 or the encapsulation layer 58.

The second functional layer is doped by the additional component 13, and the doping proportion of the additional component 13 in the second functional layer may be greater than or equal to 0.1%, and less than or equal to 100%.

By doping the material of the additional component having a higher water-oxygen reactivity in the second functional layer, it absorbs the water and oxygen diffusing from the exterior of the device to the interior of the device, thereby facilitating to improve the environmental stability of the light emitting device, and prolong the storing duration. Because the doping of the additional component 13 in the second functional layer does not influence the electrical property of the device, the doping concentration of the additional component 13 in the second functional layer may be properly increased according to demands. For example, when the second functional layer is the encapsulation layer 58, the additional component 13 may be also used as the organic packaging film layer in the encapsulation layer 58.

Optionally, as shown in FIG. 5 or FIG. 6, the light emitting device includes the electron transporting layer 54, the material of the electron transporting layer 54 includes a compound of a first metal, and the material of the additional component 13 doped in the luminescent layer 12 includes at least one of the first metal, an oxide of the first metal and an organic compound of the first metal.

The first metal may, for example, be a metal such as zinc and cadmium. Correspondingly, the material of the additional component 13 doping in the luminescent layer 12 may include one or more of the following materials: zinc, oxide of zinc, an organic compound of zinc, cadmium, oxide of cadmium, an organic compound of cadmium, and so on.

Because the electron transporting layer 54 includes a compound of the first metal, by doping the first metal and its compound in the luminescent layer 12, the substances that are generated after they absorb water and oxygen may improve the interface contact between the electron transporting layer 54 and the luminescent layer 12, thereby improving the balance of the carrier injection, and improving the performance of the device.

The present disclosure further provides a light emitting apparatus, wherein the light emitting apparatus includes the light emitting device according to any one of the above embodiments.

A person skilled in the art may understand that the light emitting apparatus has the advantages of the light emitting device described above.

In some embodiments, the light emitting apparatus may be an illuminating device. In this case, the light emitting apparatus serves as a light source, to realize the function of illumination. For example, the light emitting apparatus may be a backlight module in a liquid-crystal displaying device, a lamp for internal illumination or external illumination, or various signal lamps.

In some other embodiments, the light emitting apparatus may be a displaying device. In this case, the light emitting device is used to realize the function of displaying images (i.e., frames). The light emitting apparatus may include a display or a product including a display. The display may be a Flat Panel Display (FPD), a microdisplay and so on. If classified based on whether the user can see the scene at the back face of the display, the display may be a transparent display or a non-transparent display. If classified based on whether the display can be bent or curled, the display may be a flexible display or a common display (which may be referred to as a rigid display). As an example, the product including a display may include: a computer display, a television set, a billboard, a laser printer having the function of displaying, a telephone, a mobile phone, an electronic paper, a Personal Digital Assistant (PDA), a laptop computer, a digital camera, a tablet personal computer, a notebook computer, a navigator, a portable camcorder, a viewfinder, a vehicle, a large-area wall, a theater screen, a stadium scutcheon and so on.

The present disclosure further provides a fabricating method of a light emitting device, wherein the fabricating method includes the following steps:

Step S1: providing a substrate.

Step S2: forming a luminescent layer and an additional component on one side of the substrate, wherein the additional component is capable of having a chemical reaction with water and oxygen, and a reaction rate constant of the additional component with water and oxygen is greater than a reaction rate constant of the luminescent layer with water and oxygen.

As shown in FIGS. 1 to 3, the additional component 13 is provided in the same layer as the luminescent layer 12 and/or in a different layer from the luminescent layer 12.

The fabricating method according to the present embodiment may be used to fabricate the light emitting device according to any one of the above embodiments.

In the present embodiment, because the additional component 13 has a high reaction rate constant with water and oxygen, the additional component 13 may be formed in a protecting inert gas or in a vacuum environment, to prevent the additional component 13 from reacting with water and oxygen in the fabrication.

In an alternative implementation, in the step S2, the step of forming the luminescent layer 12 and the additional component 13 on one side of the substrate 11 may include: forming the luminescent layer 12 on one side of the substrate 11, and forming the additional component 13 on the side of the luminescent layer 12 that is away from the substrate 11; or forming the additional component 13 on one side of the substrate 11, and forming the luminescent layer 12 on the side of the additional component 13 that is opposite to the substrate 11.

The step of forming the additional component 13 may particularly include at least one of the following steps:
providing a first solution containing a material of the additional component, and coating the first solution by spin coating, spray coating or blade coating, to form the additional component 13; forming the additional component 13 by vapor deposition; and forming the additional component 13 by sputtering.

Particularly, when the additional component 13 is formed on the side of the luminescent layer 12 that is opposite to the substrate 11, the first solution may be spin-coated, spray-coated or blade-coated to the side of the luminescent layer 12 that is away from the substrate 11, and subsequently it may be treated by annealing, to form the additional component 13.

Particularly, when the additional component 13 is provided between the substrate 11 and the luminescent layer 12, the first solution may be spin-coated, spray-coated or blade-coated to the side of the substrate 11 that is close to the luminescent layer 12, and subsequently it may be treated by annealing, to form the additional component 13.

The additional component 13 obtained by fabricating according to the present implementation is an independent film layer, and may be located on the side of the luminescent layer 12 that is close to the substrate 11 or the side of the luminescent layer 12 that is further from the substrate 11.

In another alternative implementation, as shown in FIG. 5 or FIG. 6, the light emitting device may be an electroluminescent device, and accordingly the light emitting device may further include at least one of a first electrode 51, a hole injection layer 52, a hole transporting layer 53, an electron transporting layer 54, an electron injection layer 55, a second electrode 56, an optical-extraction layer 57 and an encapsulation layer 58. The layer structure relation of those film layers may refer to the description on FIG. 5 and FIG. 6, and is not discussed herein further.

The light emitting device includes a third functional layer, the third functional layer may be the first electrode 51, the hole injection layer 52, the hole transporting layer 53, the luminescent layer 12, the electron transporting layer 54, the electron injection layer 55, the second electrode 56, the optical-extraction layer 57 or the encapsulation layer 58, and the third functional layer is doped by the additional component 13.

In the present implementation, in the step S2, the step of forming the additional component 13 on one side of the substrate 11 may include at least one of the following steps:
providing a second solution containing a material of the third functional layer and a material of the additional component, and coating the second solution by spin coating, spray coating or blade coating, to synchronously form the additional component 13 doping in the third functional layer;
by vapor deposition, simultaneously vapor-depositing the material of the third functional layer and the material of the additional component, to form the additional component 13 doping in the third functional layer; and
by sputtering, simultaneously sputtering the material of the third functional layer and the material of the additional component, to form the additional component 13 doping in the third functional layer.

In a particular implementation, the additional component 13 may be doped in one or more third functional layers. Particularly, the material of the additional component may be, by means of solution processing, added into a single third functional layer, and may also be added into a plurality of third functional layers. The material of the additional component may be, by means of co-vapor deposition, added into a single third functional layer, and may also be added into a plurality of third functional layers. The material of the additional component may be, by means of co-sputtering, added into a single third functional layer, and may also be added into a plurality of third functional layers.

The fabricating method of a light emitting device will be described in detail below with reference to the particular embodiments.

In the first alternative implementation, referring to FIG. 7, the light emitting device includes an anode (i.e., the first electrode 51), the hole injection layer 52, the hole transporting layer 53, the luminescent layer 12, the electron transporting layer 54, a cathode (i.e., the second electrode 56) and a glass cover plate 71 that are arranged in stack on one side of the substrate 11. The anode is close to the substrate 11, the luminescent layer 12 is a quantum-dot layer, and the additional component 13 is doped in the quantum-dot layer (i.e., the third functional layer). In the present implementation, the material of the additional component 13 is diphenyl zinc.

In the present implementation, the fabrication of the light emitting device may include the following steps:

Step S11: performing ultrasonic washing to the substrate 11 provided with the first electrode 51 (whose material is, for example, ITO) by using sequentially anhydrous ethanol and deionized water each for 15 minutes, drying, and subsequently irradiating by using an ultraviolet lamp for 10 minutes, to increase the work function of the surface of the first electrode 51.

Step S12: depositing PEDOT:PSS as the material of the hole injection layer 52 by spin coating on the side of the washed first electrode 51 that is opposite to the substrate 11, and, optionally, subsequently annealing at 120° C. for 15 minutes, to improve the surface morphology of the hole injection layer 52, to complete the fabrication of the hole injection layer 52.

Step S13: spin-coating TFB as the material of the hole transporting layer 53 at the surface of the hole injection layer 52 that is opposite to the substrate 11, and, optionally, subsequently annealing at 120° C. for 15 minutes, to remove the solvent in the spin-coating solution.

Step S14: in a glove box with a protecting inert gas, adding 5 mg of diphenyl zinc (Ph₂Zn) into 50 mL of a quantum-dot solution, and mixing uniformly by using a high-speed mixer, to obtain a quantum-dot solution containing diphenyl zinc: and subsequently, spin-coating the quantum-dot solution containing diphenyl zinc on the side of the hole transporting layer 53 that is opposite to the substrate 11, and, optionally, subsequently annealing at 100° C. for 15 minutes, to form a flat quantum-dot layer, wherein the quantum-dot layer is doped by the diphenyl zinc as the material of the additional component.

In this step, the quantum-dot solution may be a red-color quantum-dot solution (such as a normal-octane solution), a green-color quantum-dot solution or a blue-color quantum-dot solution. In order to fabricate a color light emitting device, the step S14 may be repeated to sequentially fabricate a red-color quantum dot R, a green-color quantum dot G and a blue-color quantum dot B, to form the luminescent layer 12.

Step S15: by using a sputtering film-coating apparatus, sputtering zinc oxide as the material of the electron transporting layer 54 on the side of the quantum-dot layer that is away from the substrate 11, to form the electron transporting layer 54.

Step S16: vacuum-vapor-depositing aluminum as the electrode material on the side of the electron transporting layer 54 that is away from the substrate 11, to form the cathode (i.e., the second electrode 56).

Step 517: packaging the light emitting device by using the glass cover plate 71, to complete the fabrication of the light emitting device.

The light emitting device obtained by fabricating according to the present implementation may be a bottom-emission device.

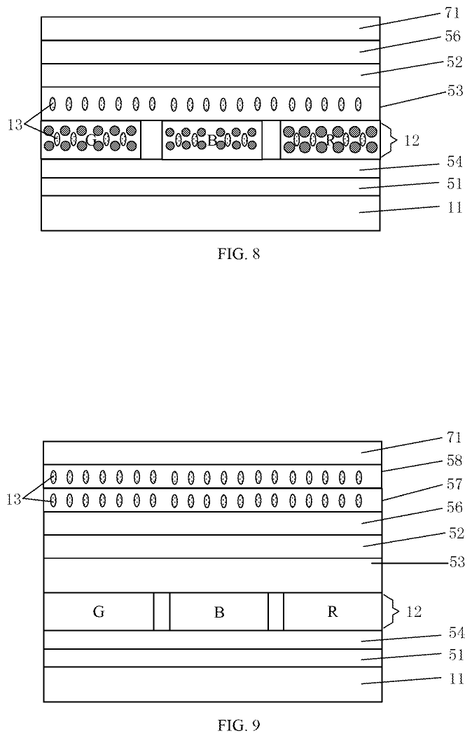

In the second alternative implementation, referring to FIG. 8, the light emitting device includes a cathode (i.e., the first electrode 51), the electron transporting layer 54, the luminescent layer 12, the hole transporting layer 53, the hole injection layer 52, an anode (i.e., the second electrode 56) and a glass cover plate 71 that are arranged in stack on one side of the substrate 11. The cathode is close to the substrate 11, the luminescent layer 12 is a quantum-dot layer, and the additional component 13 is doped in the quantum-dot layer and the hole transporting layer 53: in other words, the additional component 13 is doped in two third functional layers. In the present implementation, the material of the additional component 13 is diphenyl zinc.

In the present implementation, the fabrication of the light emitting device may include the following steps:

Step S21: performing ultrasonic washing to the substrate 11 provided with the first electrode 51 (whose material is, for example, ITO) by using sequentially anhydrous ethanol and deionized water each for 15 minutes, drying, and subsequently irradiating by using an ultraviolet lamp for 10 minutes, to increase the work function of the surface of the first electrode 51.

Step 522: depositing a ZnO nanoparticle as the material of the electron transporting layer by spin coating on the side of the washed first electrode 51 that is away from the substrate 11, and, optionally, subsequently annealing at 120° C. for 15 minutes, to improve the surface morphology of the electron transporting layer 54, to complete the fabrication of the electron transporting layer 54.

Step S23: in a glove box with a protecting inert gas, adding 5 mg of diphenyl zinc (Ph₂Zn) into 50 mL of a quantum-dot solution, and mixing uniformly by using a high-speed mixer, to obtain a quantum-dot solution containing diphenyl zinc; and subsequently, spin-coating the quantum-dot solution containing diphenyl zinc on the side of the electron transporting layer 54 that is away from the substrate 11, and, optionally, subsequently annealing at 100° C. for 15 minutes, to form a flat quantum-dot layer, wherein the quantum-dot layer is doped by the diphenyl zinc as the material of the additional component.

In this step, the quantum-dot solution may be a red-color quantum-dot solution (such as a normal-octane solution), a green-color quantum-dot solution or a blue-color quantum-dot solution. In order to fabricate a color light emitting device, the step S23 may be repeated to sequentially fabricate a red-color quantum dot R, a green-color quantum dot G and a blue-color quantum dot B, to form the luminescent layer 12.

Step S24: by using a vapor-deposition film-coating apparatus, depositing NPB as the material of the hole transporting layer and diphenyl zinc by co-vapor deposition on the side of the quantum-dot layer that is away from the substrate 11, while, by controlling the vapor-deposition speeds of them, regulating the doping proportion of the diphenyl zinc, wherein the doping concentration of the diphenyl zinc in the hole transporting layer 53 is 0.1%-10%, and after the vapor deposition is completed, the hole transporting layer 53 doped by the diphenyl zinc is formed.

Step S25: by using a vapor-deposition film-coating apparatus, vapor-depositing MoO₃ as the material of the hole injection layer on the side of the hole transporting layer 53 that is away from the substrate 11, wherein after the vapor deposition is completed, the hole injection layer 52 is formed.

Step S26: vacuum-vapor-depositing aluminum as the electrode material on the side of the hole injection layer 52 that is away from the substrate 11, to form the anode (i.e., the second electrode 56).

Step S27: packaging the light emitting device by using the glass cover plate 71, to complete the fabrication of the light emitting device.

The light emitting device obtained by fabricating according to the present implementation may be a bottom-emission device.

In the third alternative implementation, referring to FIG. 9, the light emitting device includes a cathode (i.e., the first electrode 51), the electron transporting layer 54, the luminescent layer 12, the hole transporting layer 53, the hole injection layer 52, an anode (i.e., the second electrode 56), the optical-extraction layer 57, the encapsulation layer 58 and a glass cover plate 71 that are arranged in stack on one side of the substrate 11. The cathode is close to the substrate 11, the luminescent layer 12 is a quantum-dot layer, and the additional component 13 is doped in the optical-extraction layer 57 and the encapsulation layer 58: in other words, the additional component 13 is doped in two third functional layers. In the present implementation, the material of the additional component 13 is diphenyl zinc.

In the present implementation, the fabrication of the light emitting device may include the following steps:

Step S31: performing ultrasonic washing to the substrate 11 provided with the first electrode 51 (whose material is, for example, ITO) by using sequentially anhydrous ethanol and deionized water each for 15 minutes, drying, and subsequently irradiating by using an ultraviolet lamp for 10 minutes, to increase the work function of the surface of the first electrode 51.

Step S32: depositing a ZnO nanoparticle as the material of the electron transporting layer by spin coating on the side of the washed first electrode 51 that is away from the substrate 11, and, optionally, subsequently annealing at 120° C., for 15 minutes, to improve the surface morphology of the electron transporting layer 54, to complete the fabrication of the electron transporting layer 54.

Step S33: spin-coating the quantum-dot solution on the side of the electron transporting layer 54 that is away from the substrate 11, and, optionally, subsequently annealing at 100° C. for 15 minutes, to form a flat quantum-dot layer.

In this step, the quantum-dot solution may be a red-color quantum-dot solution (such as a normal-octane solution), a green-color quantum-dot solution or a blue-color quantum-dot solution. In order to fabricate a color light emitting device, the step S33 may be repeated to sequentially fabricate a red-color quantum dot R, a green-color quantum dot G and a blue-color quantum dot B, to form the luminescent layer 12.

Step S34: by using a vapor-deposition film-coating apparatus, depositing NPB as the material of the hole transporting layer by co-vapor deposition on the side of the quantum-dot layer that is opposite to the substrate 11, to form the hole transporting layer 53.

Step S35: by using a vapor-deposition film-coating apparatus, vapor-depositing MoO₃ as the material of the hole injection layer on the side of the hole transporting layer 53 that is away from the substrate 11, to form the hole injection layer 52.

Step S36: vacuum-vapor-depositing silver as the electrode material on the side of the hole injection layer 52 that is away from the substrate 11, to form the transparent anode (i.e., the second electrode 56).

Step S37: by using a vapor-deposition film-coating apparatus, depositing the material of the optical-extraction layer 57 and diphenyl zinc by co-vapor deposition on the side of the anode (i.e., the second electrode 56) that is away from the substrate 11, while, by controlling the vapor-deposition speeds of them, regulating the doping proportion of the diphenyl zinc, wherein the doping concentration of the diphenyl zinc in the optical-extraction layer 57 is 0.1%-100%, and after the vapor deposition is completed, the optical-extraction layer 57 doped by the diphenyl zinc is formed.

Step S38: by using a vapor-deposition film-coating apparatus, depositing the material of the organic packaging film layer and diphenyl zinc by co-vapor deposition on the side of the optical-extraction layer 57 that is away from the substrate 11, while, by controlling the vapor-deposition speeds of them, regulating the doping proportion of the diphenyl zinc, wherein the doping concentration of the diphenyl zinc in the organic packaging film layer is 0.1%-100%, and after the vapor deposition is completed, the organic packaging film layer doped by the diphenyl zinc is formed.

Step 539: packaging the light emitting device by using the glass cover plate 71, to complete the fabrication of the light emitting device.

The light emitting device obtained by fabricating according to the present implementation may be a top-emission device.

The embodiments of the description are described in the mode of progression, each of the embodiments emphatically describes the differences from the other embodiments, and the same or similar parts of the embodiments may refer to each other.

Finally, it should also be noted that, in the present text, relation terms such as first and second are merely intended to distinguish one entity or operation from another entity or operation, and that does not necessarily require or imply that those entities or operations have therebetween any such actual relation or order. Furthermore, the terms “include”, “comprise” or any variants thereof are intended to cover non-exclusive inclusions, so that processes, methods, articles or devices that include a series of elements do not only include those elements, but also include other elements that are not explicitly listed, or include the elements that are inherent to such processes, methods, articles or devices. Unless further limitation is set forth, an element defined by the wording “comprising a . . . ” does not exclude additional same element in the process, method, article or device comprising the element.

The light emitting device and the fabricating method thereof, and the light emitting apparatus according to the present disclosure have been described in detail above. The principle and the embodiments of the present disclosure are described herein with reference to the particular examples, and the description of the above embodiments is merely intended to facilitate to understand the method according to the present disclosure and its core concept. Moreover, for a person skilled in the art, according to the concept of the present disclosure, the particular embodiments and the range of application may be varied. In conclusion, the contents of the description should not be understood as limiting the present disclosure.

A person skilled in the art, after considering the description and implementing the invention disclosed herein, will readily envisage other embodiments of the present disclosure. The present disclosure aims at encompassing any variations, uses or adaptive alternations of the present disclosure, wherein those variations, uses or adaptive alternations follow the general principle of the present disclosure and include common knowledge or common technical means in the art that are not disclosed by the present disclosure. The description and the embodiments are merely deemed as exemplary, and the true scope and spirit of the present disclosure are presented by the following claims.

It should be understood that the present disclosure is not limited to the accurate structure that has been described above and shown in the drawings, and may have various modifications and variations without departing from its scope. The scope of the present disclosure is merely limited by the appended claims.

The “one embodiment”, “an embodiment” or “one or more embodiments” as used herein means that particular features, structures or characteristics described with reference to an embodiment are included in at least one embodiment of the present disclosure. Moreover, it should be noted that here an example using the wording “in an embodiment” does not necessarily refer to the same one embodiment.

The description provided herein describes many concrete details. However, it can be understood that the embodiments of the present disclosure may be implemented without those concrete details. In some of the embodiments, well-known processes, structures and techniques are not described in detail, so as not to affect the understanding of the description.

In the claims, any reference signs between parentheses should not be construed as limiting the claims. The word “comprise” does not exclude elements or steps that are not listed in the claims. The word “a” or “an” preceding an element does not exclude the existing of a plurality of such elements. The present disclosure may be implemented by means of hardware comprising several different elements and by means of a properly programmed computer. In unit claims that list several devices, some of those devices may be embodied by the same item of hardware. The words first, second, third and so on do not denote any order. Those words may be interpreted as names.

Finally, it should be noted that the above embodiments are merely intended to explain the technical solutions of the present disclosure, and not to limit them. Although the present disclosure is explained in detail with reference to the above embodiments, a person skilled in the art should understand that he can still modify the technical solutions set forth by the above embodiments, or make equivalent substitutions to part of the technical features of them. However, those modifications or substitutions do not make the essence of the corresponding technical solutions depart from the spirit and scope of the technical solutions of the embodiments of the present disclosure.

1. A light emitting device, wherein the light emitting device comprises: a substrate, and a luminescent layer and an additional component that are provided on one side of the substrate, the additional component is capable of having a chemical reaction with water and oxygen, and a reaction rate constant of the additional component with water and oxygen is greater than a reaction rate constant of the luminescent layer with water and oxygen; and
the additional component is provided in a same layer as the luminescent layer and/or in a different layer from the luminescent layer.

2. The light emitting device according to claim 1, wherein the additional component and the luminescent layer are arranged in a same layer, the additional component and the luminescent layer are mixed, and a molar volume fraction of the luminescent layer is greater than a molar volume fraction of the additional component.

3. The light emitting device according to claim 1, wherein the additional component and the luminescent layer are arranged in different layers, the additional component is provided between the luminescent layer and the substrate, or the additional component is provided on one side of the luminescent layer that is away from the substrate.

4. The light emitting device according to claim 1, wherein a material of the additional component comprises at least one of a metal, a metal oxide and an organometallic compound.

5. The light emitting device according to claim 4, wherein a material of the additional component comprises at least one of an organic compound of lithium, an organic compound of sodium, an organic compound of zinc, an organic compound of cadmium, an organic compound of iron and an organic compound of titanium.

6. The light emitting device according to claim 5, wherein a material of the additional component comprises at least one of diethyl zinc, dimethyl zinc, dibutyl zinc, diphenyl zinc, diethyl cadmium, dimethyl cadmium, dibutyl cadmium, diphenyl cadmium, butyl lithium, tert-butyl lithium, methyl lithium and benzyl lithium.

7. The light emitting device according to claim 1, wherein a thickness of the additional component is greater than or equal to 0.1 nm, and less than or equal to 10 nm.

8. The light emitting device according to claim 1, wherein the luminescent layer comprises an organic luminescent material or a quantum dot.

9. The light emitting device according to claim 1, wherein the light emitting device further comprises at least one of a first electrode, a hole injection layer, a hole transporting layer, an electron transporting layer, an electron injection layer, a second electrode, an optical-extraction layer and an encapsulation layer;
the first electrode, the hole injection layer, the hole transporting layer, the luminescent layer, the electron transporting layer, the electron injection layer, the second electrode, the optical-extraction layer and the encapsulation layer are arranged in stack on one side of the substrate, and the first electrode is close to the substrate: or the first electrode, the electron injection layer, the electron transporting layer, the luminescent layer, the hole transporting layer, the hole injection layer, the second electrode, the optical-extraction layer and the encapsulation layer are arranged in stack on one side of the substrate, and the first electrode is close to the substrate; and
the position of the additional component includes at least one of: provided between at least one group of neighboring film layers among the substrate, the first electrode, the hole injection layer, the hole transporting layer, the luminescent layer, the electron transporting layer, the electron injection layer, the second electrode, the optical-extraction layer and the encapsulation layer, provided on one side of the encapsulation layer that is away from the substrate, and doped in at least one of the first electrode, the hole injection layer, the hole transporting layer, the luminescent layer, the electron transporting layer, the electron injection layer, the second electrode, the optical-extraction layer and the encapsulation layer.

10. The light emitting device according to claim 9, wherein the light emitting device comprises a first functional layer, and the first functional layer is the first electrode, the hole injection layer, the hole transporting layer, the luminescent layer, the electron transporting layer, the electron injection layer or the second electrode; and
the first functional layer is doped by the additional component, and a doping proportion of the additional component in the first functional layer is greater than or equal to 0.1%, and less than or equal to 10%.

11. The light emitting device according to claim 9, wherein the light emitting device comprises a second functional layer, and the second functional layer comprises the optical-extraction layer or the encapsulation layer; and
the second functional layer is doped by the additional component, and a doping proportion of the additional component in the second functional layer is greater than or equal to 0.1%, and less than or equal to 100%.

12. The light emitting device according to claim 9, wherein the light emitting device comprises the electron transporting layer, a material of the electron transporting layer comprises a compound of a first metal, and a material of the additional component doped in the luminescent layer comprises at least one of the first metal, an oxide of the first metal and an organic compound of the first metal.

13. A light emitting apparatus, wherein the light emitting apparatus comprises the light emitting device according to claim 1.

14. A fabricating method of a light emitting device, wherein the fabricating method comprises:
providing a substrate; and
forming a luminescent layer and an additional component on one side of the substrate, wherein the additional component is capable of having a chemical reaction with water and oxygen, and a reaction rate constant of the additional component with water and oxygen is greater than a reaction rate constant of the luminescent layer with water and oxygen;
wherein the additional component is provided in a same layer as the luminescent layer and/or in a different layer from the luminescent layer.

15. The fabricating method according to claim 14, wherein the step of forming the luminescent layer and the additional component on one side of the substrate comprises at least one of:
providing a first solution containing a material of the additional component, and coating the first solution by spin coating, spray coating or blade coating, to form the additional component;
forming the additional component by vapor deposition; and
forming the additional component by sputtering.

16. The fabricating method according to claim 14, wherein the light emitting device further comprises at least one of a first electrode, a hole injection layer, a hole transporting layer, an electron transporting layer, an electron injection layer, a second electrode, an optical-extraction layer and an encapsulation layer;
the light emitting device comprises a third functional layer, the third functional layer is the first electrode, the hole injection layer, the hole transporting layer, the luminescent layer, the electron transporting layer, the electron injection layer, the second electrode, the optical-extraction layer or the encapsulation layer, and the third functional layer is doped by the additional component; and
the step of forming the luminescent layer and the additional component on one side of the substrate comprises at least one of:
providing a second solution containing a material of the third functional layer and a material of the additional component, and coating the second solution by spin coating, spray coating or blade coating, to form the additional component doped in the third functional layer;
by vapor deposition, vapor-depositing the material of the third functional layer and the material of the additional component at the same time, to form the additional component doped in the third functional layer; and
by sputtering, sputtering the material of the third functional layer and the material of the additional component at the same time, to form the additional component doped in the third functional layer.
